(19) United States
(12) Patent Application Publication
(10) Pub. No.: US 2025/0160063 A1
(43) Pub. Date: May 15, 2025

(54) LIGHT EMITTING ELEMENT

(71) Applicant: TOYODA GOSEI CO., LTD., Kiyosu-shi (JP)

(72) Inventors: Hiroaki MAKINO, Kiyosu-shi (JP); Hideki OMOYA, Kiyosu-shi (JP); Koichi MIZUTANI, Kiyosu-shi (JP); Shinichi MATSUI, Kiyosu-shi (JP); Masaki OYA, Kiyosu-shi (JP)

(21) Appl. No.: 18/937,890

(22) Filed: Nov. 5, 2024

(30) Foreign Application Priority Data
Nov. 9, 2023 (JP) 2023-191507
Jun. 27, 2024 (JP) 2024-104139

(51) Int. Cl. H01L 33/32; H01L 33/38; H01L 33/42; H01L 33/44

(52) U.S. Cl. CPC H10H 20/825; H10H 20/8316; H10H 20/833; H10H 20/84

(57) ABSTRACT

A light emitting element of a face-up type using a group III nitride semiconductor emits light with wavelengths of 210 to 300 nm. The light emitting element has an n-type layer, an active layer provided on the n-type layer, a p-type layer provided on the active layer, an n-side electrode provided on the n-type layer and having a comb shape, a p-side contact electrode provided on and in contact with the p-type layer and transmitting light of the wavelength, and a p-side electrode provided on the p-side contact electrode and having a comb shape. The p-side electrode has p-side extending portions extending in a direction. The n-side electrode has n-side extending portions extending in the direction, each n-side extending portion being disposed between the p-side extending portions adjacent to the n-side extending portion. A distance between the p-side extending portion and the n-side extending portion is 140 μm or less.

### CROSS-REFERENCE TO RELATED APPLICATIONS

This application is based on and claims priority under 35 USC 119 from Japanese Patent Application No. 2023-191507 filed on Nov. 9, 2023 and Japanese Patent Application No. 2024-104139 filed on Jun. 27, 2024, the entire content of which is incorporated herein by reference.

### TECHNICAL FIELD

The present disclosure relates to a light emitting element.

### BACKGROUND ART

It is known that light emitting elements using a group III nitride semiconductor include a flip-chip structure in which light is extracted from a back surface side of a substrate and a face-up structure in which light is extracted from a side opposite to a substrate. In a case of blue light emission, the flip-chip type is used for high-output applications such as a headlamp, and the face-up type is used for low-output applications such as a backlight.

A light emitting element using a group III nitride semiconductor can emit light with a wavelength of 210 nm to 280 nm. It is known that ultraviolet light in the UVC region (100 nm to 280 nm) can efficiently sterilize and inactivate bacteria and viruses, and the market for UVC-LED that use a group III nitride semiconductors is expanding.

JP2022-019963A and JP2019-176016A each discloses a face-up type UVC-LED. It is widely known that an n-side electrode and a p-side electrode are formed in a comb shape in a face-up type blue LED. JP2017-028032A, JP2022-014593A and JP2022-043972A disclose that an n-side electrode and a p-side electrode are formed in a comb shape in a flip-chip type UVC-LED.

In recent years, the market for UVC-LEDs has expanded, and face-up type UVC-LEDs are also in demand. However, the face-up type UVC-LEDs have not been put to practical use due to low light output and high forward voltage Vf.

### SUMMARY OF INVENTION

An object of the present disclosure is to provide a light emitting element of the face-up type for ultraviolet light emission, which is capable of improving light output and reducing forward voltage.

An aspect of the present disclosure provides a light emitting element of a face-up type using a group III nitride semiconductor and having an emission wavelength of 210 nm to 300 nm, the light emitting element including:
an n-type layer made of an n-type group III nitride semiconductor;
an active layer provided on the n-type layer and made of a group III nitride semiconductor;
a p-type layer provided on the active layer and made of a p-type group III nitride semiconductor;
an n-side electrode provided on the n-type layer and having a comb shape;
a p-side contact electrode provided on the p-type layer to be in contact with the p-type layer, and transmitting light of the emission wavelength; and
a p-side electrode provided on the p-side contact electrode and having a comb shape,
in which the p-side electrode has a plurality of p-side extending portions extending in a predetermined direction,
the n-side electrode has a plurality of n-side extending portions extending in the predetermined direction, each n-side extending portion being disposed between the p-side extending portions adjacent to the n-side extending portion, and
a distance between the p-side extending portion and the n-side extending portion is 140 μm or less.

In the above aspect, the p-side electrode and the n-side electrode are provided in the comb shape, and an interval between the p-side extending portion of the p-side electrode and the n-side extending portion of the n-side electrode is 140 μm or less. Therefore, it is possible to improve the light output and reduce the forward voltage.

### BRIEF DESCRIPTION OF DRAWINGS

Exemplary embodiment(s) of the present invention will be described in detail based on the following figures, wherein:

FIG. 1 is a cross-sectional view showing a configuration of a light emitting element according to an embodiment, the cross section being perpendicular to a main surface of a substrate;

FIG. 2 is a diagram of the light emitting element according to the embodiment as viewed from above, showing an electrode pattern;

FIG. 3 is a diagram showing an electrode pattern of a light emitting element according to a comparative example;

FIG. 4 is a graph showing a relationship between forward current and light output;

FIG. 5 is a graph showing current-voltage characteristics; and

FIG. 6 is a graph showing a relationship between the number of n-side extending portions and wall-plug efficiency.

### DESCRIPTION OF EMBODIMENTS

A light emitting element is of the face-up type, has an emission wavelength of 210 nm to 300 nm, and uses a group III nitride semiconductor. The light emitting element includes: an n-type layer that is made of an n-type group III nitride semiconductor; an active layer that is provided on the n-type layer and made of a group III nitride semiconductor; a p-type layer that is provided on the active layer and made of a p-type group III nitride semiconductor; an n-side electrode that is provided on the n-type layer and has a comb shape; a p-side contact electrode that is provided on the p-type layer to be in contact with the p-type layer, and transmits light of the emission wavelength; and a p-side electrode that is provided on the p-side contact electrode and has a comb shape. The p-side electrode has a plurality of p-side extending portions extending in a predetermined direction. The n-side electrode has a plurality of n-side extending portions extending in the predetermined direction. Each n-side extending portion is disposed between the p-side extending portions adjacent to the n-side extending portion. A distance between the p-side extending portion and the n-side extending portion is 140 μm or less.

In the light emitting element, a distance between the p-side extending portion and the n-side extending portion may be 30 μm or more. It is possible to suppress the inhibition of light extraction by the p-side electrode. The distance is more preferably 50 μm or more and 130 μm or less.

In the light emitting element, the p-side contact electrode may be made of one oxide selected from groups of ITO and IZO. A thickness of the p-side contact electrode may be 40 nm or less. It is possible to make good contact with the p-type layer while allowing ultraviolet light of the emission wavelength to pass through.

In the light emitting element, the p-side contact electrode may be made of one metal selected from groups of Ru, Rh, Mg, an alloy mainly containing Ru, Rh, and/or Mg, and Ni/Au. A thickness of the p-side contact electrode may be 10 nm or less. It is possible to make good contact with the p-type layer while allowing ultraviolet light of the emission wavelength to pass through.

In the light emitting element, the p-side electrode may include a p-side pad portion and the plurality of p-side extending portions extending in the predetermined direction from the p-side pad portion. The n-side electrode may include an n-side pad portion and the plurality of n-side extending portions extending from the n-side pad portion in the predetermined direction. Each n-side extending portion may be disposed between the p-side extending portions adjacent to the n-side extending portion. A distance between the p-side pad portion and the n-side extending portion may be 150 μm or less. A distance between the p-side extending portion and the n-side pad portion may be 150 μm or less. In the light emitting element, a distance between the p-side pad portion and the n-side extending portion may be 50 μm or more, and a distance between the p-side extending portion and the n-side pad portion may be 30 μm or more.

In the light emitting element, a distance between a center line of the p-side extending portion and a center line of the n-side extending portion may be 140 μm or less. The in-plane diffusion of current can be improved.

In the light emitting element, a width of the n-side extending portion and a width of the p-side extending portion may be 5 μm or more and 20 μm or less.

In the light emitting element, the p-type layer may have a p-type contact layer being in contact with the p-side contact electrode and made of GaN, and a thickness of the p-type contact layer may be 1 nm or more and 50 nm or less.

In the light emitting element, the p-type layer may have a p-type contact layer being in contact with the p-side contact electrode and made of AlGaN having an Al composition of 50% or less, and a thickness of the p-type contact layer may be 20 nm or less.

In the light emitting element, the n-side electrode may have the three or more n-side extending portions. The n-side electrode may especially have the four or more and seven or less n-side extending portions.

In the light emitting element, an anti-reflection film may be provided on the p-side contact electrode in a region where the p-side electrode is not provided. In the light emitting element, an anti-reflection film may be provided on the p-side contact electrode, and the anti-reflection film may be provided on the p-side electrode in a region excluding the p-side pad portion.

### First Embodiment

### 1. Overview of Light Emitting Element

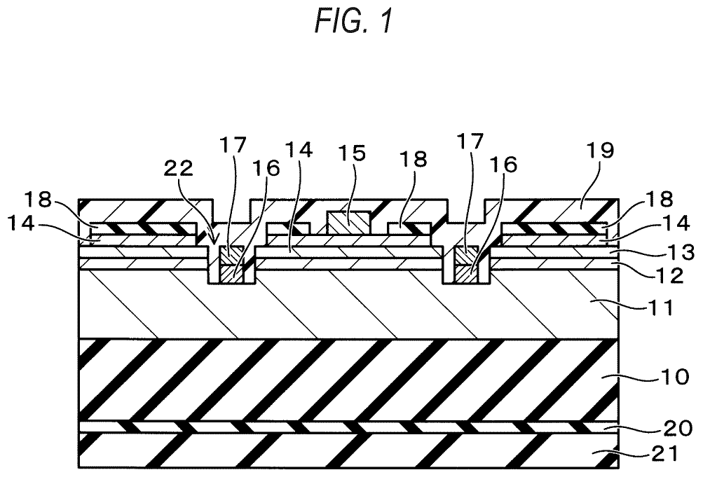

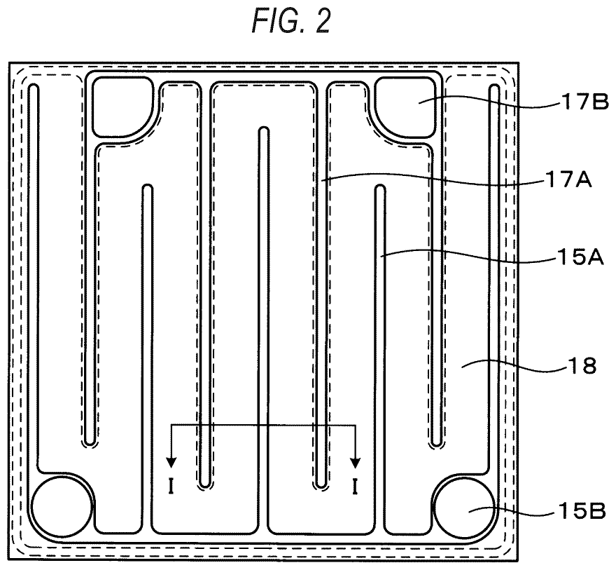

FIG. 1 is a cross-sectional view showing a configuration of a light emitting element according to an embodiment, the cross section being perpendicular to a main surface of a substrate. FIG. 2 is a diagram of the light emitting element according to the embodiment as viewed from above, showing an electrode pattern. FIG. 1 is a cross section taken along I-I in FIG. 2.

As shown in FIG. 1, the light emitting element according to the embodiment includes a substrate 10, an n-type layer 11, an active layer 12, a p-type layer 13, a p-side contact electrode 14, a p-side electrode 15, an n-side contact electrode 16, an n-side electrode 17, an anti-reflection film 18, a protective film 19, an adhesion layer 20, and a back surface reflection film 21.

The light emitting element according to the embodiment is the face-up type in which light is extracted from a side (electrode side) opposite to the substrate 10. An emission wavelength is a predetermined wavelength in a range of 210 nm to 300 nm, and can also be in the UVC band (100 nm to 280 nm).

### 2. Configuration of Light Emitting Element

Next, a configuration of the light emitting element according to the embodiment will be described in detail.

The substrate 10 is a substrate made of sapphire and has a c-plane as a main surface. The main surface of the sapphire may have an a-plane orientation. The plane orientation may have an off angle of 0.1 to 2 degrees in an m-axis direction. The substrate 10 may be an AlN substrate or an AlN template substrate in which an AlN layer is formed on a sapphire substrate.

A thickness of the substrate 10 is, for example, 1000 μm or less. The thickness of the substrate 10 is preferably 400 μm or more and 700 μm or less.

The back surface reflection film 21 is provided on a back surface of the substrate 10 via the adhesion layer 20. The adhesion layer 20 is a layer for improving adhesion between the substrate 10 and the back surface reflection film 21. The adhesion layer 20 is made of SiO₂. The back surface reflection film 21 is made of a metal having a high reflectance with respect to the ultraviolet light of the emission wavelength. For example, Al, Mg, or an alloy containing Al and Mg as main components. By providing the back surface reflection film 21, the ultraviolet light emitted from the active layer 12 and directed toward the substrate 10 is reflected toward the electrode, thereby improving the light extraction efficiency. A DBR may be used as the back surface reflection film 21.

The n-type layer 11 is located on the substrate 10. The n-type layer 11 is made of n-AlGaN. An Al composition (molar ratio of Al in all group III metals) is, for example, 60% to 90%. An n-type impurity is Si, and a Si concentration is, for example, 1×10¹⁸ cm⁻³ to 5×10¹⁹ cm⁻³. A thickness of the n-type layer 11 is, for example, 0.5 μm to 5 μm. A C concentration of the n-type layer 11 is 1×10¹⁵ cm⁻³ to 1×10¹⁹ cm⁻³. The n-type layer 11 may include a plurality of layers. For example, the n-type layer 11 may be a superlattice layer in which AlGaN having different Al compositions are alternately stacked. Further, a base layer made of AlN may be provided between the substrate 10 and the n-type layer 11. In addition, materials other than Si may be used as the n-type impurity.

The active layer 12 is located on the n-type layer 11. The active layer 12 has an SQW structure in which a barrier layer, a well layer, and a barrier layer are stacked in this order from the n-type layer 11 side. The active layer 12 may have an MQW structure. In this case, the number of repetitions is, for example, 2 to 10.

The well layer is made of AlGaN, and an Al composition thereof is set according to a desired emission wavelength. A Si concentration of the well layer is, for example, 1×10¹⁸ cm⁻³ or less, and may be non-doped. A thickness of the well layer is, for example, 0.5 nm to 5 nm.

The barrier layer is made of AlGaN having an Al composition higher than that of the well layer, and the Al composition is, for example, 50% to 100%. A Si concentration of the barrier layer is, for example, 2×10¹⁹ cm⁻³ or less, and may be non-doped. A thickness of the barrier layer is, for example, 3 nm to 30 nm. The barrier layer may be AlGaInN having band gap energy larger than that of the well layer. Among the barrier layers, a layer in contact with an electron blocking layer preferably has a thickness of 0.5 nm to 10 nm.

A hole blocking layer may be provided between the n-type layer 11 and the active layer 12. Holes injected from the p-side electrode 15 can be suppressed from going beyond the active layer 12 and diffusing toward the n-type layer 11 side. The hole blocking layer is AlGaN or AlN having an Al composition higher than that of the barrier layer of the active layer 12. A thickness of the hole blocking layer is, for example, one molecular layer to 2 nm. In the case of AlN, one molecular layer is about 0.26 nm.

The p-type layer 13 is located on the active layer 12. The p-type layer 13 has a structure in which an electron blocking layer, a composition gradient layer, and a p-type contact layer are stacked in this order from the active layer 12 side.

The electron blocking layer has a two-layer structure in which a first electron blocking layer and a second electron blocking layer are stacked in this order from the active layer 12 side. The electron blocking layers suppress electrons injected from the n-side contact electrode 16 from going beyond the active layer 12 and diffusing toward the p-type layer 13 side.

Note that, the electron blocking layer does not necessarily have a two-layer structure, and may include only the first electron blocking layer.

The first electron blocking layer is made of AlGaN or AlN having an Al composition ratio higher than that of a barrier layer of the active layer 12, and the Al composition is, for example, 90% to 100%. In addition, the first electron blocking layer may be doped with a p-type impurity or may be non-doped. The p-type impurity is, for example, Mg. In the case of Mg-doped, a Mg concentration is, for example, 3×10²⁰ cm⁻³ or less. A thickness of the first electron blocking layer is, for example, 1 nm to 10 nm.

The second electron blocking layer is made of AlGaN having an Al composition lower than that in the first electron blocking layer, and the Al composition is, for example, 80% to 99%. When the second electron blocking layer is provided, a difference in Al composition from the composition gradient layer is adjusted. A resistance is increased when the first electron blocking layer is made of only AlN, and when the first electron blocking layer is thinned, an electron blocking performance decreases. Therefore, the second electron blocking layer is provided to achieve both a low resistance and an electron blocking function. In addition, the second electron blocking layer may be doped with a p-type impurity or may be non-doped. In the case of Mg-doped, a Mg concentration is, for example, 3×10²⁰ cm⁻³ or less. A thickness of the second electron blocking layer is, for example, 1 nm to 10 nm.

The composition gradient layer is located on the electron blocking layer. The composition gradient layer has a two-layer structure in which a first composition gradient layer and a second composition gradient layer are stacked in this order from the electron blocking layer.

The composition gradient layer is a p-type layer formed by a method called polarization doping. That is, the composition gradient layer is a layer in which an Al composition changes in a thickness direction, and is set such that the Al composition is reduced as a distance from the electron blocking layer increases. It is difficult to increase a hole concentration in AlGaN having a high Al composition when doped with Mg, but the hole concentration can be improved by polarization doping, and the efficiency of hole injection into the active layer 12 can be increased. Since the polarization doping does not require doping with Mg, crystallinity can be improved.

When the Al composition of the composition gradient layer is set as described above, polarization due to strain of the crystal occurs continuously in the thickness direction in the composition gradient layer. Holes are generated in the composition gradient layer so as to cancel out fixed charges due to the polarization. The generated holes are distributed in the composition gradient layer. Therefore, the holes are widely distributed in the thickness direction from the electron blocking layer side in the composition gradient layer, and the layer become a p type as a whole. In a p-type region, the hole concentration is 1×10¹⁶ cm⁻³ to 1×10²⁰ cm⁻³, and the hole concentration decreases as the distance from the electron blocking layer increases.

A maximum value of an Al composition of the first composition gradient layer (an Al composition at an interface between the first composition gradient layer and the electron blocking layer) is preferably a value that is 1% to 20% lower than the Al composition of the electron blocking layer. The hole concentration can be further increased by polarization due to strain. For example, the maximum value of the Al composition is 65% to 95%.

A minimum value of the Al composition of the first composition gradient layer (an Al composition at an interface between the first gradient layer and the second composition gradient layer) is preferably set to a value that is 3% to 30% lower than the maximum value of the Al composition of the first composition gradient layer. The hole concentration can be further increased by polarization due to strain. In addition, an Al composition having band energy that does not absorb the emission wavelength is preferable.

A reduction rate of the Al composition of the first composition gradient layer is preferably 0.1%/nm to 0.3%/nm. In such a range, the hole concentration of the first composition gradient layer can be further increased. The reduction rate of the Al composition may be constant, that is, may change linearly, or may not be constant.

The first composition gradient layer is non-doped. Alternatively, it may be Mg-doped. Further improvement in hole concentration can be expected due to the p-type impurity. In this case, the Mg concentration is, for example, 1×10²⁰ cm⁻³ or less.

The second composition gradient layer is a layer having a Mg concentration higher than that in the first composition gradient layer, and an Al composition in the second composition gradient layer is set to be similar to that in the first composition gradient layer. That is, the second composition gradient layer is a layer in which the Al composition changes in a thickness direction and is set such that the Al composition is reduced as the distance from the electron blocking layer increases. The second composition gradient layer can be well connected to the p-type contact layer by being doped with Mg.

A difference between a maximum value of the Al composition of the second composition gradient layer (an Al composition at an interface between the second composition gradient layer and the first composition gradient layer) and a minimum value of the AI composition of the first composition gradient layer is 0% to 5%, and the maximum value of the AI composition of the second composition gradient layer is preferably the same as the minimum value of the Al composition of the first composition gradient layer. That is, the Al composition is preferably continuous from the first composition gradient layer to the second composition gradient layer.

A minimum value of the Al composition of the second composition gradient layer (an Al composition at an interface between the second composition gradient layer and the p-type contact layer) is preferably a value that is 3% to 30% lower than the maximum value of the Al composition of the second composition gradient layer.

A reduction rate of the Al composition of the second composition gradient layer is in the same range as the reduction rate of the Al composition of the first composition gradient layer. The reduction rate of the Al composition of the second composition gradient layer may be the same as the reduction rate of the Al composition of the first composition gradient layer.

A Mg concentration of the second composition gradient layer is freely set as long as the Mg concentration of the second composition gradient layer is higher than the Mg concentration of the first composition gradient layer, and the Mg concentration of the second composition gradient layer is preferably 3×10²⁰ cm⁻³ or less. This is to suppress series resistance.

Note that, the Al composition of the composition gradient layer is continuously decreased in the first embodiment. Alternatively, the Al composition may be decreased stepwise. It is preferable that a region where the Al composition is constant is as small as possible.

A ratio of the thickness of the first composition gradient layer in the composition gradient layer is preferably 0.4 to 0.7. In this range, the contact between the composition gradient layer and the p-type contact layer can be improved while sufficiently improving the hole concentration by polarization doping. More preferably, the ratio is 0.4 to 0.6.

The composition gradient layer does not necessarily have a two-layer structure including the first composition gradient layer and the second composition gradient layer, and may include only the first composition gradient layer. In addition, the composition gradient layer may have a structure of three or more layers having different change rates of the Al composition, different Mg concentrations, and the like.

A ratio of the thickness of the composition gradient layer to a total film thickness of the electron blocking layer, the composition gradient layer, and the p-type contact layer is preferably 50% or more and 90% or less. Within this range, the function of the p-type layer can be sufficiently enhanced.

Instead of the composition gradient layer, a layer made of Mg-doped p-type AlGaN may be provided. In this case, a Mg concentration is, for example, 1×10¹⁷ cm⁻³ to 1×10¹⁹ cm⁻³. An Al composition is, for example, 40% to 80%.

The p-type contact layer is located on the composition gradient layer. The p-type contact layer is made of Mg-doped p-GaN. The p-type contact layer may be p-AlGaN having an Al composition of 50% or less. The Al composition is more preferably 30% or less.

When the p-type contact layer is made of GaN, the thickness is preferably set to 1 nm or more and 50 nm or less. GaN absorbs ultraviolet light emitted from the active layer 12, but can transmit ultraviolet light by making it sufficiently thin. Therefore, a large decrease in external quantum efficiency can be avoided. The thickness is preferably 1 nm or more and 10 nm or less. The Mg concentration of the p-type contact layer is, for example, 1×10²⁰ cm⁻³ to 1×10²² cm⁻³.

When the p-type contact layer is made of AlGaN, it may include a plurality of layers having different Al compositions or Mg concentrations. In this case, the thickness of the p-type contact layer is preferably 20 nm or less. By sufficiently reducing the thickness, the ultraviolet light can be transmitted. The Mg concentration is the same as that in the case of GaN.

A groove 22 having a depth reaching the n-type layer 11 is provided in a partial region of a surface of the p-type layer 13. The groove 22 is for exposing the n-type layer 11 so that the n-side contact electrode 16 and the n-side electrode 17 can be provided. Therefore, a planar pattern of the groove 22 is a slightly enlarged version of a planar patterns of the n-side contact electrode 16 and the n-side electrode 17. The planar pattern of the n-side contact electrode 16 and the n-side electrode 17 will be described later.

The p-side contact electrode 14 is provided in contact with the p-type layer 13. The p-side contact electrode 14 is provided over the entire surface of the p-type layer 13 except for end portions. The p-side contact electrode 14 diffuses the current widely within the plane, increasing a light emitting area and improving the light output.

The p-side contact electrode 14 is made of ITO. In addition, a material that can provide a good contact with the p-type contact layer and transmits ultraviolet light of the emission wavelength may be used. For example, a conductive oxide such as IZO, metals such as Ru, Rh, Mg, alloys containing Ru, Rh, and Mg as main components, and Ni/Au may be used. A thickness is preferably set so as to provide a transmittance of 50% or more for the ultraviolet light of the emission wavelength. When a conductive oxide is used, the thickness of the p-side contact electrode 14 is preferably 40 nm or less. When a metal is used, the thickness of the p-side contact electrode 14 is preferably 10 nm or less.

The p-side electrode 15 is provided in a partial region on the p-side contact electrode 14. A material of the p-side electrode 15 is, for example, Ti/Ni/Au/Al.

As shown in FIG. 2, the p-side electrode 15 has a comb-shaped planar pattern and includes a p-side extending portion 15A and a p-side pad portion 15B. The p-side extending portion 15A is a region provided to diffuse current in the plane. The p-side pad portion 15B is a region on which a p-side pad electrode is provided. The p-side pad electrode is connected to the outside by a wire. Details of the planar pattern of the p-side electrode 15 will be described later.

The anti-reflection film 18 is provided in contact with the p-side contact electrode 14 in a region on the p-side contact electrode 14 where the p-side electrode 15 is not provided. An upper surface of the anti-reflection film 18 is in contact with the protective film 19. By providing the anti-reflection film 18, reflection between the p-side contact electrode 14 and the protective film 19 can be suppressed, and the light extraction efficiency from the upper surface of the element can be improved. Further, the anti-reflection film 18 may be provided in contact with the p-side electrode 15 in a region on the p-side electrode 15 excluding the p-side pad portion 15B. That is, the anti-reflection film may also be provided on and in contact with the p-side extending portion 15A. This makes it possible to further improve the light extraction efficiency.

The anti-reflection film 18 is a single layer or a multilayer in which materials having different refractive indices are alternately laminated, and has a structure that reduces reflection by optical interference with a layer having a predetermined thickness. When the anti-reflection film 18 is a single layer, the refractive index (a value at the emission wavelength) of the anti-reflection film 18 is preferably 1.4 to 1.9. For example, HfO₂, ZrO₂, SiO₂, Al₂O₃, MgF₂, and the like may be used.

The n-side contact electrode 16 is provided on the n-type layer 11 exposed at a bottom surface of the groove 22. The material of the n-side contact electrode 16 is, for example, V/Al/Ti.

The n-side electrode 17 is provided on the n-side contact electrode 16. A material of the n-side electrode 17 is, for example, Ti/Ni/Au/Al. The p-side electrode 15 and the n-side electrode 17 may be made of the same material.

As shown in FIG. 2, the n-side contact electrode 16 and the n-side electrode 17 have a comb-shaped planar pattern, and include an n-side extending portion 17A and an n-side pad portion 17B. The n-side extending portion 17A is a region provided to diffuse current in the plane. The n-side pad portion 17B is a region on which an n-side pad electrode is provided. The n-side pad electrode is connected to the outside by a wire. Details of the planar pattern of the n-side contact electrode 16 and the n-side electrode 17 will be described later.

The protective film 19 is provided so as to cover the entire upper surface of the element except for the p-side pad portion 15B and the n-side pad portion 17B. A material for the protective film is SiO₂ or the like.

### 2. Planar Pattern of Electrodes

Next, the planar patterns of the p-side electrode 15, the n-side contact electrode 16, and the n-side electrode 17 will be described with reference to FIG. 2.

As shown in FIG. 2, the p-side electrode 15 has a comb shape, and includes five linear p-side extending portions 15A and the p-side pad portions 15B connected to the p-side extending portions 15A. The light emitting element according to the embodiment has a rectangular shape in a plan view, and the p-side extending portions 15A extend from the vicinity of one edge of the rectangle in a direction perpendicular to that edge. Further, the five p-side extending portions 15A are arranged at equal intervals. The p-side pad portions 15B are disposed at corners at both ends of one edge of the rectangle, and the p-side extending portions 15A extend from the p-side pad portions 15B.

As shown in FIG. 2, the n-side contact electrode 16 and the n-side electrode 17 have a comb shape, and have four linear n-side extending portions 17A and the n-side pad portions 17B connected to the n-side extending portions 17A. The n-side extending portions 17A extend from the vicinity of an edge opposite to the edge on which the p-side pad portions 15B are disposed in a direction perpendicular to that edge. The n-side extending portion 17A is intermediately disposed between the adjacent p-side extending portions 15A. Two n-side pad portions 17B are arranged at a predetermined distance in the vicinity of the edge opposite to the edge on which the p-side pad portions 15B are disposed, and the n-side extending portions 17A extend from the n-side pad portions 17B.

A distance D1 between the p-side extending portion 15A and the n-side extending portion 17A is 140 μm or less. By setting the distance D1 to 140 μm or less, it is possible to efficiently diffuse the current within the plane, and it is possible to improve the light output and reduce the forward voltage. For the same reason, a distance D2 between the center line of the p-side extending portion 15A and the center line of the n-side extending portion 17A is preferably 140 μm or less.

The distance D1 is preferably 30 μm or more. This is because as the distance D1 becomes shorter, an area of the p-side extending portion 15A increases, and the reflection and absorption of ultraviolet light by the p-side extending portion 15A inhibits light extraction. The distance is preferably 50 μm or more and 130 μm or less, and further preferably 60 μm or more and 100 μm or less.

A distance D3 between the p-side pad portion 15B and the n-side extending portion 17A is preferably 150 μm or less. This is to allow the current to be efficiently diffused within the plane. For the same reason, a distance D4 between the p-side extending portion 15A and the n-side pad portion 17B is preferably 150 μm or less.

A width W1 of the p-side extending portion 15A and a width W2 of the n-side extending portion 17A are preferably 5 μm or more and 20 μm or less. By setting the widths W1 and W2 in this manner, it is possible to achieve a balance between the diffusion of the current by the p-side extending portion 15A and the n-side extending portion 17A and a reduction in the light emitting area due to the p-side extending portion 15A and the n-side extending portion 17A.

In the embodiment, there are five p-side extending portions 15A and four n-side extending portions 17A. The embodiment is not limited thereto. The number of the n-side extending portions 17A is preferably three or more. The number of the n-side extending portions 17A is further preferably four or more and seven or less. By providing four or more n-side extending portions, the in-plane diffusion of current can be improved, and the light output can be largely improved. The reason why the number is seven or less is that the improvement of the light output due to the increase of the number tends to reach a plateau around seven, and the light output tends to decrease when the number increases over seven. It is assumed that the areas of the p-side extending portion 15A and the n-side extending portion 17A increase as the number of the n-side extending portion 17A increases so that the inhibition of light extraction is largely effected.

The light emitting element in the embodiment has a rectangular shape in a plane view. A length of the short side is, for example, 500 μm to 1500 μm, and a length of the long side is, for example, 500 μm to 1500 μm. Within the range, it is possible to sufficiently improve the in-plane diffusion of the current due to the p-side extending portion 15A and the n-side extending portion 17A. The p-side extending portion 15A and the n-side extending portion 17A may extend in the long side direction, or may extend in the short side direction.

In the embodiment, two p-side pad portions 15B and two n-side pad portions 17B are provided, but the number is not limited to this, and one p-side pad portion and one n-side pad portion may be provided. By providing two or more p-side pad portions 15B and two or more n-side pad portions 17B, it becomes easy to diffuse the current uniformly in the plane.

### 3. Summary

In a face-up type light emitting element having an emission wavelength of 210 nm to 300 nm, the p-side contact electrode 14 is designed to transmit the ultraviolet light of the emission wavelength. Therefore, it is necessary to thin the p-side contact electrode 14. However, as a result, the in-plane diffusion of current is deteriorated, which causes a decrease in light output and a deterioration in forward voltage.

Therefore, in the light emitting element according to the embodiment, the planar patterns of the p-side electrode 15, the n-side contact electrode 16, and the n-side electrode 17 are comb-shaped. Each n-side extending portion 17A is disposed between the p-side extending portions 15A adjacent to the n-side extending portion 17A. The distance between the p-side extending portion 15A and the n-side extending portion 17A is set to 140 μm or less. By setting the electrode pattern in this manner, in-plane diffusion of current can be improved, and improvement of light output and reduction in forward voltage can be achieved.

### 4. Explanation of Experimental Results

### Experiment 1

A light emitting element (hereinafter, referred to as a light emitting element according to the example) was prepared with a structure in which the anti-reflection film 18 was omitted from the light emitting element according to the embodiment, and the light output and the current-voltage characteristics were measured. The planar pattern of the electrode was as shown in FIG. 2, with D1 being 101 μm, D2 being 121 μm, D3 being 73 μm, D4 being 100 μm, W1 being 20 μm, and W2 being 20 μm. Further, an area of the p-side contact electrode 14 was 0.80 mm², an area of the n-side contact electrode 16 was 0.11 mm², and an area of the p-side electrode 15 was 0.13 mm².

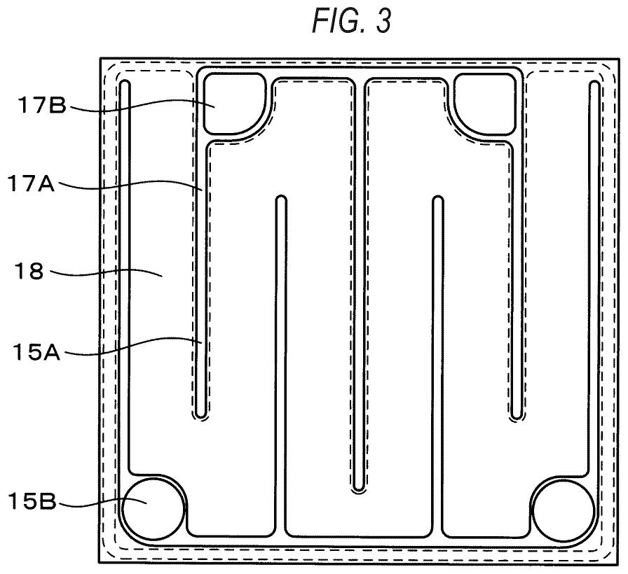

For comparison, a light emitting element (hereinafter, referred to as a light emitting element according to the comparative example) was produced in which the electrode pattern was changed as shown in FIG. 3. The configuration other than the electrode pattern is the same as that of the light emitting element according to the example. In the electrode pattern of the light emitting element according to the comparative example, as shown in FIG. 3, the p-side extending portions 15A and the n-side extending portions 17A were reduced by one, and D1 was set to 141 μm compared to those in FIG. 2. Further, an area of the p-side contact electrode 14 was 0.85 mm², an area of the n-side contact electrode 16 was 0.09 mm², and an area of the p-side electrode 15 was 0.11 mm².

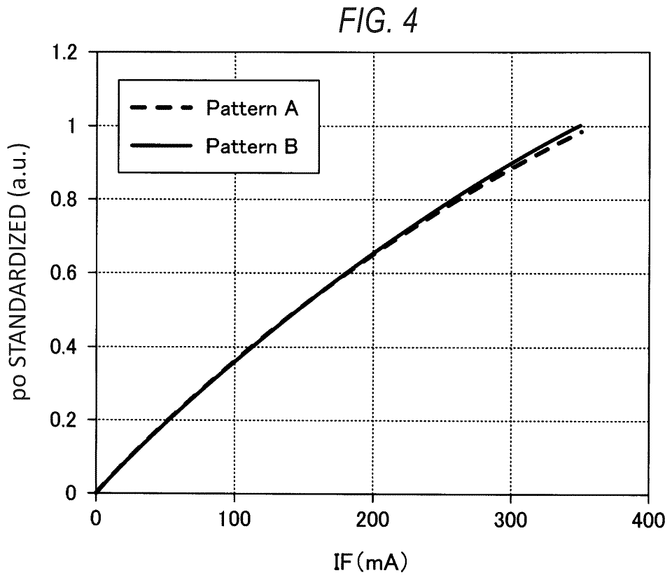

FIG. 4 is a graph showing the relationship between forward current and light output for the light emitting elements according to the example and the comparative example. The light output is a standardized value assuming that the light output of the light emitting element according to the example at 350 mA is 1. As shown in FIG. 4, the light emitting element according to the example had a higher light output than the light emitting element according to the comparative example. At 350 mA, the light output of the light emitting element according to the comparative example was 98% of the light output of the light emitting element according to the example.

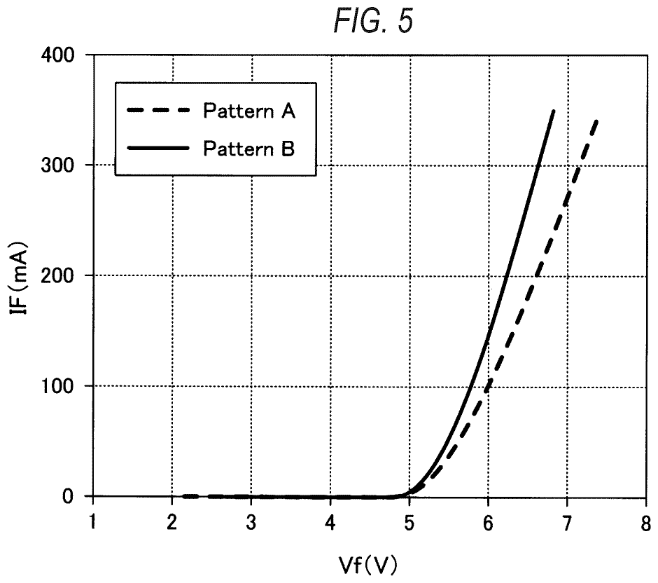

FIG. 5 is a graph showing the I-V characteristics of the light emitting elements according to the example and the comparative example. As shown in FIG. 5, the light emitting element according to the example had a lower forward voltage than the light emitting element according to the comparative example. At 350 mA, the forward voltage of the light emitting element according to the comparative example was 7.39 V, while the forward voltage of the light emitting element according to the example was 6.78 V.

From the results of FIGS. 4 and 5, it was found that the distance between the n-side extending portion 17A and the p-side extending portion 15A is preferably set to 140 μm or less.

### Experiment 2

For the light emitting element having the same configuration with Experiment 1, the wall-plug efficiency (WPE) was simulated by changing the number of the n-side extending portions 17A between three and seven. The light emitting element has a square shape in a plane view, and a length of one side thereof is 1000 μm. The electrode pattern is the same with Experiment 1, and the number of the p-side extending portions 15A is equal to “the number of the n-side extending portions 17A plus one”. The width W1 of the p-side extending portion 15A and the width W2 of the n-side extending portion 17A are 20 μm.

The distance D1 between the p-side extending portion 15A and the n-side extending portion 17A varies according to the number of the n-side extending portions 17A, and the correspondence is as follows: D1 is 161 μm in the case of three; D1 is 121 μm in the case of four; D1 is 97 μm in the case of five; D1 is 81 μm in the case of six; and D1 is 69 μm in the case of seven.

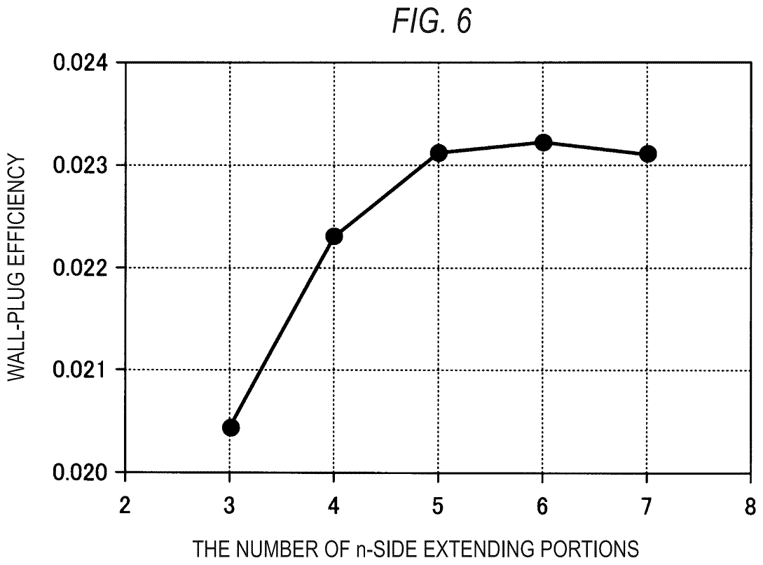

FIG. 6 is a graph showing a relationship between the number of the n-side extending portions 17A and the WPE (wall-plug efficiency). As shown in FIG. 6, when the number of the n-side extending portions 17A is four or more, the wall-plug efficiency significantly increases. It is assumed that the in-plane diffusion of the current is improved by increasing the number of the n-side extending portions 17A. When the number of the n-side extending portions 17A increases from five to six, the wall-plug efficiency slightly increases. When the number of the n-side extending portions 17A is six, the wall-plug efficiency is maximized. When the number of the n-side extending portions 17A further increases from six to seven, the wall-plug efficiency slightly decreases. Thus, it is assumed that the wall-plug efficiency will further decrease when the number of the n-side extending portions 17A is eight or more. The reason why the wall-plug efficiency decreases when the number of the n-side extending portions 17A is seven or more is that the areas of the n-side extending portion 17A and the p-side extending portion 15A increase by increasing the number of the n-side extending portions 17A and the p-side extending portions 15A so that the light extraction is affected due to the inhibition by the electrodes.

Consequently, as referring to the result in FIG. 6, it was found that the number of the n-side extending portions 17A was preferably four to seven, and was particularly preferable to be five to seven. It was found that the distance D1 between the p-side extending portion 15A and the n-side extending portion 17A was preferably 50 nm to 130 nm, and was particularly preferable to be 60 nm to 100 nm.

What is claimed is:

1. A light emitting element of a face-up type using a group III nitride semiconductor and having an emission wavelength of 210 nm to 300 nm, the light emitting element comprising:
an n-type layer made of an n-type group III nitride semiconductor;
an active layer provided on the n-type layer and made of a group III nitride semiconductor;
a p-type layer provided on the active layer and made of a p-type group III nitride semiconductor;
an n-side electrode provided on the n-type layer and having a comb shape;
a p-side contact electrode provided on the p-type layer to be in contact with the p-type layer, and transmitting light of the emission wavelength; and
a p-side electrode provided on the p-side contact electrode and having a comb shape,
wherein the p-side electrode has a plurality of p-side extending portions extending in a predetermined direction,
the n-side electrode has a plurality of n-side extending portions extending in the predetermined direction, each n-side extending portion being disposed between the p-side extending portions adjacent to the n-side extending portion, and
a distance between the p-side extending portion and the n-side extending portion is 140 μm or less.

2. The light emitting element according to claim 1,
wherein a distance between the p-side extending portion and the n-side extending portion is 30 μm or more.

3. The light emitting element according to claim 1,
wherein the p-side contact electrode is made of one oxide selected from groups of ITO and IZO, and
a thickness of the p-side contact electrode is 40 nm or less.

4. The light emitting element according to claim 1,
wherein the p-side contact electrode is made of one metal selected from groups of Ru, Rh, Mg, an alloy mainly containing Ru, Rh, and/or Mg, and Ni/Au, and
a thickness of the p-side contact electrode is 10 nm or less.

5. The light emitting element according to claim 1,
wherein the p-side electrode includes a p-side pad portion and the plurality of p-side extending portions extending in the predetermined direction from the p-side pad portion,
the n-side electrode includes an n-side pad portion and the plurality of n-side extending portions extending from the n-side pad portion in the predetermined direction, each n-side extending portion being disposed between the p-side extending portions adjacent to the n-side extending portion,
a distance between the p-side pad portion and the n-side extending portion is 150 μm or less, and
a distance between the p-side extending portion and the n-side pad portion is 150 μm or less.

6. The light emitting element according to claim 5,
wherein a distance between the p-side pad portion and the n-side extending portion is 50 μm or more, and
a distance between the p-side extending portion and the n-side pad portion is 30 μm or more.

7. The light emitting element according to claim 1,
wherein a distance between a center line of the p-side extending portion and a center line of the n-side extending portion is 140 μm or less.

8. The light emitting element according to claim 1,
wherein a width of the n-side extending portion and a width of the p-side extending portion are 5 μm or more and 20 μm or less.

9. The light emitting element according to claim 1,
wherein the p-type layer has a p-type contact layer being in contact with the p-side contact electrode and made of GaN, and
a thickness of the p-type contact layer is 1 nm or more and 50 nm or less.

10. The light emitting element according to claim 1,
wherein the p-type layer has a p-type contact layer being in contact with the p-side contact electrode and made of AlGaN having an Al composition of 50% or less, and
a thickness of the p-type contact layer is 20 nm or less.

11. The light emitting element according to claim 1,
wherein the n-side electrode has the three or more n-side extending portions.

12. The light emitting element according to claim 11,
wherein the n-side electrode has the three or more n-side extending portions.

13. The light emitting element according to claim 1,
wherein a distance between the p-side extending portion and the n-side extending portion is 50 μm or more and 130 μm or less.

14. The light emitting element according to claim 1,
wherein an anti-reflection film is provided on the p-side contact electrode in a region where the p-side electrode is not provided.

15. The light emitting element according to claim 5,
wherein an anti-reflection film is provided on the p-side contact electrode, and the anti-reflection film is provided on the p-side electrode in a region excluding the p-side pad portion.
